(19) United States
(12) Patent Application Publication
(10) Pub. No.: US 2025/0349742 A1
(43) Pub. Date: Nov. 13, 2025

(54) SEMICONDUCTOR PACKAGE

(71) Applicant: SAMSUNG ELECTRONICS CO., LTD., SUWON-SI (KR)

(72) Inventors: Yongjin SEOL, Suwon-si (KR); Deok Hee HAN, Suwon-si (KR)

(21) Appl. No.: 18/973,358

(22) Filed: Dec. 9, 2024

(30) Foreign Application Priority Data
May 9, 2024 (KR) 10-2024-0061165

(51) Int. Cl. H01L 23/00; H01L 21/48; H01L 23/31; H01L 23/498

(52) U.S. Cl. CPC H01L 23/562; H01L 23/3128; H01L 23/49833; H01L 23/49838; H01L 21/4853; H01L 24/16; H01L 2224/16227; H01L 2224/16238; H01L 2924/1815

(57) ABSTRACT

A semiconductor package includes: a first re-wiring layer including a first wiring; a semiconductor die placed on the first re-wiring layer; a post placed on the first re-wiring layer, and spaced apart from the semiconductor die, wherein the post is electrically connected to the first wiring; and a reinforcement structure including a first reinforcement part and a second reinforcement part, wherein the first reinforcement is placed on the first re-wiring layer, and is spaced apart from the semiconductor die and the post such that it is placed between the semiconductor die and the post, and wherein the second reinforcement part protrudes from the first reinforcement part.

### CROSS-REFERENCE TO RELATED APPLICATION

This application claims priority under 35 U.S.C. § 119 to Korean Patent Application No. 10-2024-0061165, filed on May 9, 2024, in the Korean Intellectual Property Office, the disclosure of which is incorporated by reference herein in its entirety.

### TECHNICAL FIELD

Example embodiments of the present inventive concept relate to a semiconductor package, and more particularly, to a semiconductor package including a reinforcement structure.

### DISCUSSION OF THE RELATED ART

As mobile devices become smaller, the thickness of semiconductor packages also decreases. However, as the thickness of the semiconductor package decreases, cracks or breakage may occur in the semiconductor die that is included in the semiconductor package, even under a mild impact.

### SUMMARY

According to example embodiments of the present inventive concept, a semiconductor package includes: a first re-wiring layer including a first wiring; a semiconductor die placed on the first re-wiring layer; a post placed on the first re-wiring layer, and spaced apart from the semiconductor die, wherein the post is electrically connected to the first wiring; and a reinforcement structure including a first reinforcement part and a second reinforcement part, wherein the first reinforcement is placed on the first re-wiring layer, and is spaced apart from the semiconductor die and the post such that it is placed between the semiconductor die and the post, and wherein the second reinforcement part protrudes from the first reinforcement part.

According to example embodiments of the present inventive concept, a semiconductor package includes: a first re-wiring layer including a first wiring; a semiconductor die placed on the first re-wiring layer; a post placed on the first re-wiring layer, and spaced apart from the semiconductor die, wherein the post is electrically connected to the first wiring; and a reinforcement structure including a third reinforcement part and a fourth reinforcement part, wherein the third reinforcement part is placed on the first re-wiring layer, and is spaced apart from the semiconductor die and the post such that it is placed between the semiconductor die and the post, wherein the third reinforcement part has a substantially constant thickness, and wherein the fourth reinforcement part is connected to the third reinforcement part and has a thickness that is thicker than that of the third reinforcement part.

According to example embodiments of the present inventive concept, a semiconductor package includes: a first re-wiring layer including a first wiring; a semiconductor die placed on the first re-wiring layer; a post placed on the first re-wiring layer, and spaced apart from the semiconductor die, wherein the post is electrically connected to the first wiring; a reinforcement structure including a first reinforcement part and a second reinforcement part, wherein the first reinforcement part is placed on the first re-wiring layer, and is spaced apart from the semiconductor die and the post, and wherein the second reinforcement part protrudes from the first reinforcement part in a direction toward the semiconductor die; a molding member covering an upper surface of the first re-wiring layer and at least partially surrounding the semiconductor die, the reinforcement structure and the post on the first re-wiring layer, wherein the molding member fills spaces that are between the semiconductor die, the reinforcement structure and the post; and a second re-wiring layer placed on the post and the molding member, and including a second wiring that is electrically connected to the post and the first wiring.

### BRIEF DESCRIPTION OF THE DRAWINGS

The above and other aspects and features of the present inventive concept will become more apparent by describing in detail embodiments thereof with reference to the attached drawings, in which:

FIG. 1 is a cross-sectional view of a semiconductor package according to an example embodiment of the present inventive concept;

FIG. 2 is an enlarged view of a part A of FIG. 1;

FIG. 3 is a cross-sectional view of the semiconductor package taken along line I-I of FIG. 1;

FIG. 4 is a diagram of testing a semiconductor package in a test socket according to an example embodiment of the present inventive concept;

FIGS. 5, 6, 7 and 8 are diagrams illustrating cross sections taken along line I-I of FIG. 1;

FIG. 9 illustrates a cross section of a semiconductor package according to an example embodiment of the present inventive concept;

FIG. 10 is an enlarged view of a part C of FIG. 9;

FIGS. 11, 12 and 13 are diagrams for explaining a method of forming a post and a reinforcement structure that are included in a semiconductor package according to an example embodiment of the present inventive concept;

FIG. 14 is a cross-sectional view of a semiconductor package according to an example embodiment of the present inventive concept; and

FIG. 15 is an enlarged view of the part A of FIG. 1.

### DETAILED DESCRIPTION OF THE EMBODIMENTS

It is to be understood that terms or words that are used in the specification and claims should not be construed as being limited to their common or dictionary meanings. Further, each of the terms or words should be interpreted with a meaning and concept that is consistent with the technical idea of the present inventive concept based on the principle that the inventor may appropriately define the concept of terms to explain his or her invention.

In the specification and figures, like reference numerals may denote like elements or features, and thus, repetitive descriptions may be omitted.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, or an intervening element (for example, a third element) may be between the element and another element.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. For example, components or elements combined with these ordinal numbers should not be interpreted as having a limited order of use or arrangement based on the number. If necessary, each ordinal number may be used interchangeably.

Hereinafter, example embodiments of the present inventive concept will be described in detail with reference to the attached drawings. However, the spirit and scope of the present inventive concept should not be limited to the example embodiments set forth herein because the present inventive concept may be embodied in various different forms. In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

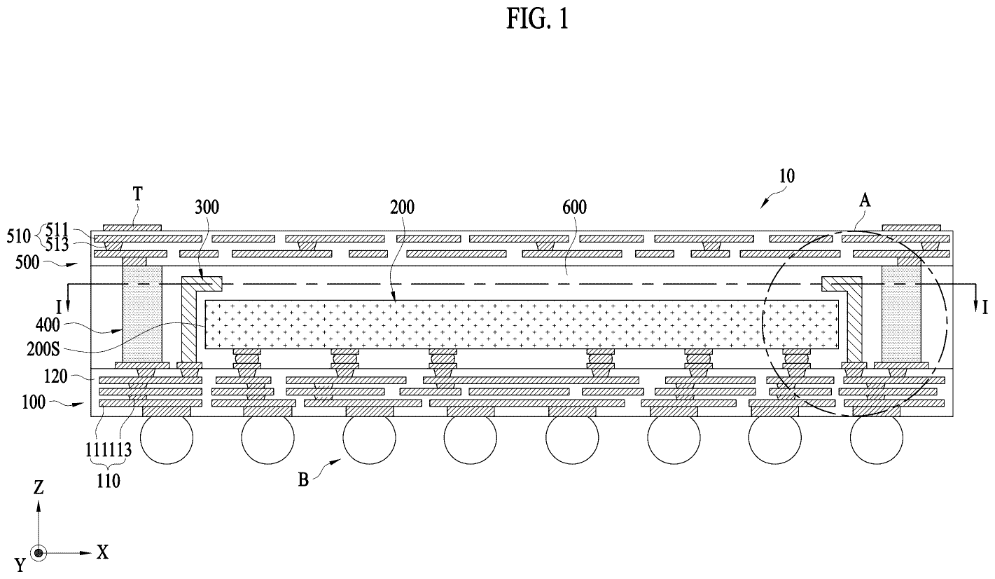

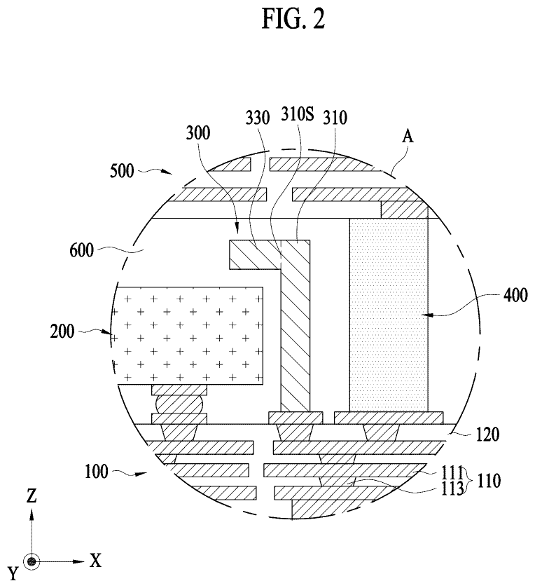

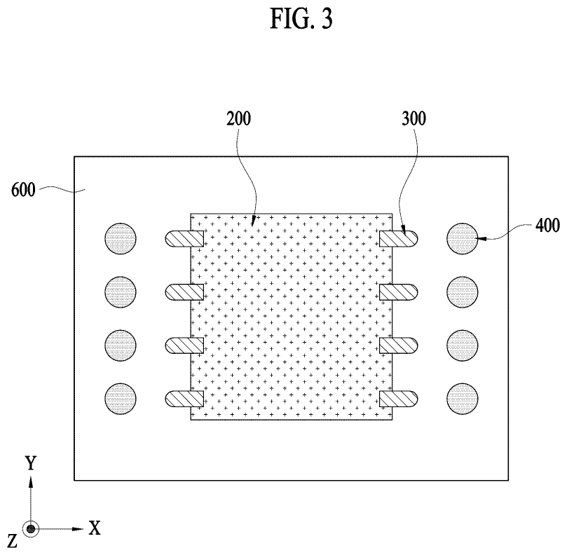

FIG. 1 is a cross-sectional view of a semiconductor package according to an example embodiment of the present inventive concept. FIG. 2 is an enlarged view of the part A of FIG. 1. FIG. 3 is a cross-sectional view of the semiconductor package taken along line I-I of FIG. 1.

Referring to FIGS. 1 to 3, a semiconductor package 10 may include a first re-wiring layer 100, a semiconductor die 200, a reinforcement structure 300 and a post 400.

According to example embodiments of the present inventive concept, the first re-wiring layer 100 may include a first wiring 110. The first re-wiring layer 100 may include an insulating layer 120. The first wiring 110 may be placed within the insulating layer 120. For example, the first re-wiring layer 100 may include a plurality of insulating layers 120 that may be stacked on each other. The first wiring 110 may include a plurality of first wiring patterns 111 and a plurality of first vias 113 vertically connecting each of the plurality of first wiring patterns 111 to each other. The first wiring 110 may include a conductive material. For example, the first wiring 110 may include at least one of gold (Au), silver (Ag), copper (Cu), nickel (Ni), or aluminum (Al).

According to example embodiments of the present inventive concept, the semiconductor die 200 may be a logic chip and may be placed on the first re-wiring layer 100. For example, the semiconductor die 200 may be an application processor (AP) chip. However, the semiconductor die 200 is not limited thereto. For example, the semiconductor die 200 may be a central processing unit (CPU) chip, a graphic processing unit (GPU) chip, or a memory chip.

According to example embodiments of the present inventive concept, the post 400 may be placed adjacent to one side of the first re-wiring layer 100. The post 400 may be spaced apart from the semiconductor die 200 in a direction that is parallel to an upper surface of the first re-wiring layer 100 (e.g., any direction in the X-Y plane). For example, the post 400 may be spaced apart from the semiconductor die 200 in the horizontal direction (e.g., the first direction X or the second direction Y). The post 400 may be disposed adjacent to an outer circumference 200S of the semiconductor die 200. For example, the post 400 maybe spaced apart from the outer circumference 200s of the semiconductor die 200. The post 400 may be electrically connected to the first wiring 110. The post 400 may be formed to have a length (or, e.g., a height) that is longer than a length of a first reinforcement part 310 of the reinforcement structure 300, which will be described later, based on a direction that is perpendicular to the upper surface of the first re-wiring layer 100 (the third direction Z).

According to example embodiments of the present inventive concept, the reinforcement structure 300 may include the first reinforcement part 310 and a second reinforcement part 330. In an example embodiment of the present inventive concept, the first reinforcement part 310 may be a rod-shaped structure that protrudes in the third direction Z and is disposed on the first re-wiring layer 100. The first reinforcement part 310 may be spaced apart from the semiconductor die 200 and the post 400 in a direction parallel to the upper surface of the first re-wiring layer 100 (e.g., any direction in the X-Y plane). For example, the first reinforcement part 310 may be spaced apart from the semiconductor die 200 and the post 400 in the horizontal direction (the first direction X or the second direction Y). The first reinforcement part 310 may be placed between the semiconductor die 200 and the post 400. The second reinforcement part 330 may be a structure that protrudes in a certain direction from an outer circumference 310S (or, e.g., a side surface) of the first reinforcement part 310. For example, the second reinforcement part 330 may be formed by protruding from the outer circumference 310S located at an upper portion of the first reinforcement part 310, and the second reinforcement part 330 may be formed to protrude in a direction toward the semiconductor die 200 and in a horizontal direction (the first direction X or the second direction Y).

According to example embodiments of the present inventive concept, the reinforcement structure 300 and the post 400 may include conductive materials such as copper (Cu), nickel (Ni), silver (Ag), gold (Au), iron (Fe) and combinations thereof. The reinforcement structure 300 and the post 400 may be formed by a plating process. Spaces, in which reinforcement structure 300 and the post 400 are to be formed, may be formed with photoresist through a photo process, and then the reinforcement structure 300 and the post 400 may be formed by filling the spaces with conductive material through a plating process. Alternatively, the reinforcement structure 300 and the post 400 may be replaced with already manufactured parts.

Referring to FIGS. 1 to 3, the semiconductor package 10 may further include a second re-wiring layer 500, a molding member 600, an external terminal T and a bump B.

According to example embodiments of the present inventive concept, the molding member 600 may be placed on the first re-wiring layer 100. The molding member 600 may cover the upper surface of the first re-wiring layer 100. The molding member 600 may at least partial surround the semiconductor die 200, the reinforcement structure 300, and the post 400. For example, the molding member 600 may seal the semiconductor die 200, the reinforcement structure 300 and the post 400.

According to example embodiments of the present inventive concept, the molding member 600 may include a thermosetting resin, a thermoplastic resin, a UV-curable resin, or a combination thereof. For example, the molding member 600 may include epoxy resin, silicone resin, or a combination thereof. However, the molding member 600 is not limited thereto. The molding member 600 may include an epoxy mold compound (EMC).

According to example embodiments of the present inventive concept, the second re-wiring layer 500 may include a second wiring 510. The second wiring 510 may include a plurality of second wiring patterns 511 and a plurality of second vias 513 vertically connecting each of the plurality of second wiring patterns 511 to each other. The second re-wiring layer 500 may be placed on the post 400 and the molding member 600. The second re-wiring layer 500 may be electrically connected to the post 400 and the first wiring 110. The remaining description of the second re-wiring layer 500 may at least be similar to the description of the first re-wiring layer 100 described above, and may thus be omitted.

According to example embodiments of the present inventive concept, the external terminal T may be placed on the second re-wiring layer 500. The external terminal T may be electrically connected to the second re-wiring layer 500. The external terminal T may overlap the post 400 in a direction that is substantially perpendicular to the upper surface of the first re-wiring layer 100 (e.g., the third direction Z). The external terminal T may be spaced apart from the semiconductor die 200 and may be further away from the semiconductor die 200 than the reinforcement structure 300 in the horizontal direction (the first direction X or the second direction Y). The external terminal T may include a conductive material such as copper (Cu), nickel (Ni), silver (Ag), gold (Au), iron (Fe), and a combination thereof. The external terminal T may be formed to protrude from the upper surface of the second re-wiring layer 500. The external terminal T may electrically connect the semiconductor package 10 according to example embodiments of the present inventive concept and a another semiconductor package to each other. For example, the separate semiconductor package 10 may be a memory chip.

According to example embodiments of the present inventive concept, the bump B may be placed on the first re-wiring layer 100. For example, the bump B may be disposed on a lower surface of the first re-wiring layer 100. The bump B may include a solder ball or a solder bump. For example, the bump B may have a spherical or elliptical shape, but the present inventive concept is not limited thereto. The number, spacing, arrangement, and shape of the bump B are not limited to those illustrated, and the number, spacing, arrangement, and shape of the bump B may vary depending on the design. For example, the bump B may include tin (Sn), indium (In), bismuth (Bi), antimony (Sb), copper (Cu), silver (Ag), zinc (Zn), lead (Pb), and combinations thereof. However, the bump B is not limited thereto.

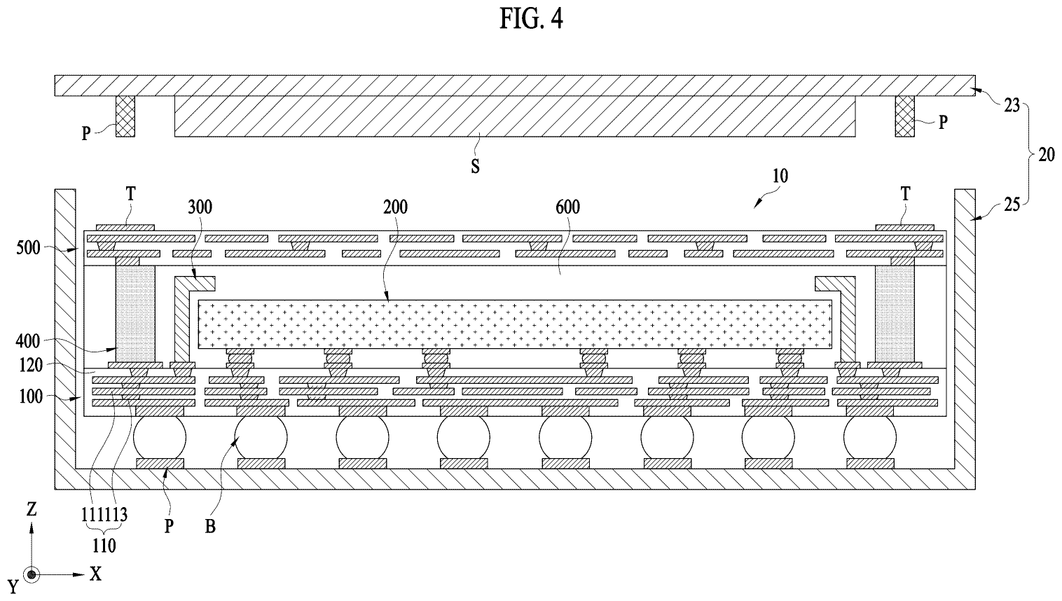

The effect of the semiconductor package 10 according to embodiments of the present inventive concept will be described in detail with reference to FIG. 4.

FIG. 4 is a diagram of testing the semiconductor package 10 in a test socket 20 according to an example embodiment of the present inventive concept.

According to example embodiments of the present inventive concept, the durability against compressive stress, bending stress, and shear stress of the semiconductor package 10 may be increased. Referring to FIG. 4, after packaging is completed, the semiconductor package 10 may be inspected by using the test socket 20, which checks the semiconductor package 10 for defects by supplying electricity to the semiconductor package 10 and testing the semiconductor package 10. The test socket 20 may include a lower part socket 25 and an upper part socket 23. The lower part socket 25 accommodates the semiconductor package 10, and the upper part socket 23 moves toward the semiconductor package 10 that is accommodated in the lower part socket 25 to come into contact with the external terminal T. While the upper socket 23 is in contact with the external terminal T, the upper part socket 23 pressurizes the semiconductor package 10. During the test process, the upper part socket 23 pressurizes the semiconductor package 10, and thus, stress is applied to the semiconductor die 200 that is within the semiconductor package 10. To fix the semiconductor package 10 during the pressurizing process, the upper part socket 23 may include a fixation part S that comes into contact with the upper surface of the semiconductor package 10. For example, the fixation part S may include an adsorption pad having a vacuum pressure passage, and a vacuum force may be applied to the adsorption pad. If all test pins P of the upper part socket 23 are pressurized with the same pressure, compressive stress may be applied to the semiconductor package 10, and the post 400 that is disposed at a position overlapping the external terminal T in the vertical direction (the third direction Z) may resist compressive stress. The fixation part S also pressurizes the semiconductor package 10 so that the bump B may contact a test pin P of the lower part socket 25. During the process, compressive stress may act on the semiconductor package 10. To more effectively resist compressive stress that is caused by the fixation part S, the reinforcement structure 300 may be arranged to overlap the fixation part S in the vertical direction (the third direction Z). In the vertical direction (the third direction Z), the edge of the fixation part S may overlap the position of the first reinforcement part 310.

However, during the test process, the test pin P and the fixation part S of the upper part socket 23 cannot pressurize the semiconductor package 10 with exactly the same pressure, and thus, bending stress and shear stress may be applied to the semiconductor package 10 due to asymmetrical pressurization of the test pin P or asymmetrical pressurization by the fixation part S. In addition, during the actual use of the semiconductor package 10, bending stress, shear stress and so on may be applied to the semiconductor package 10. To effectively resist stresses other than compressive stress, reinforcement structures 300 may be provided in the horizontal direction (the first direction X or the second direction Y), in addition to reinforcement structures 300 that are provided in the vertical direction (the third direction Z). The second reinforcement part 330 of the reinforcement structure 300 provided in the horizontal direction (the first direction X or the second direction Y) may be at least partially surrounded by the molding member 600, and thus, the second reinforcement part 330 may be integrated with the molding member 600 and may effectively resist bending stress, shear stress and so on. Therefore, the durability of the semiconductor package 10 may be increased.

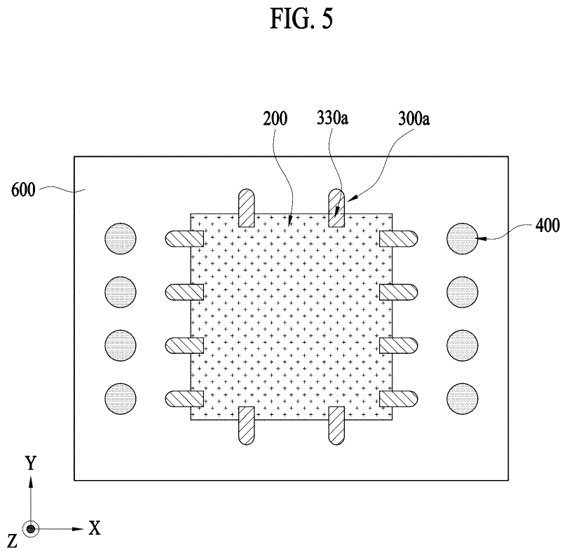

FIGS. 5 to 8 are diagrams illustrating cross sections taken along line I-I of FIG. 1.

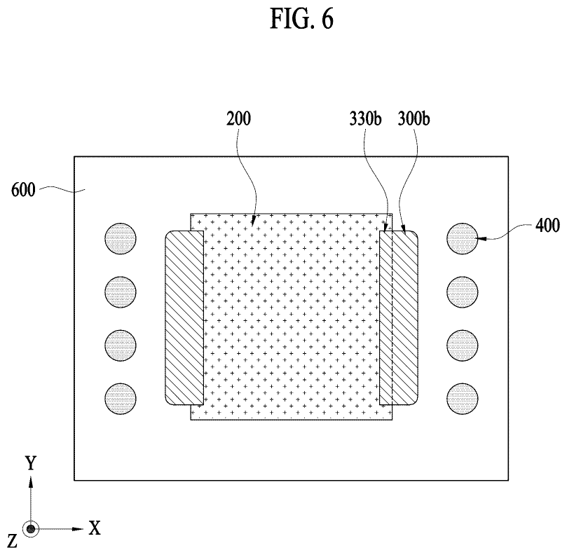

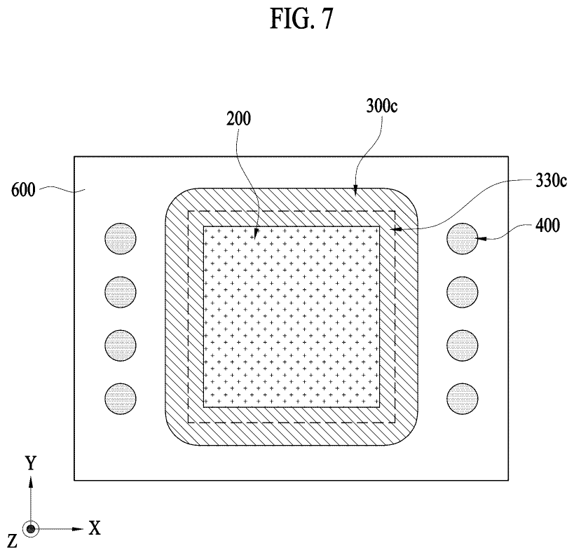

Referring to FIGS. 5 to 7, at least some of the second reinforcement parts 330a, 330b and 330c may be located on a level that is above a level of the upper surface of the semiconductor die 200 based on the direction that is perpendicular to the upper surface of the first re-wiring layer 100 (the third direction Z). At least some of the second reinforcement parts 330a, 330b and 330c may overlap the semiconductor die 200 based on the direction that is perpendicular to the upper surface of the first re-wiring layer 100 (the third direction Z). Specifically, as illustrated in FIG. 5, a plurality of second reinforcement parts 330a of a plurality of reinforcement structures 300a may be arranged to be spaced apart from each other by a predetermined distance along the outer edge of the semiconductor die 200, and accordingly, the plurality of second reinforcement parts 330a may be placed on all sides in different horizontal directions (e.g., the first direction X and the second direction Y) to increase the durability of the semiconductor package 10. In addition, according to an embodiment of the present inventive concept, as illustrated in FIG. 6, each of the second reinforcement parts 330b of a reinforcement structure 300b may be arranged to overlap one side of the semiconductor die 200. For example, the second reinforcement parts 330b may be arranged to respectively overlap a pair of opposing sides of the semiconductor die 200 in the third direction Z. For example, each of the second reinforcement parts 330b may extend along one side of the semiconductor die 200. In addition, according to an embodiment of the present inventive concept, as illustrated in FIG. 7, the second reinforcement part 330c of a reinforcement structure 300c may be arranged to overlap all sides of the semiconductor die 200.

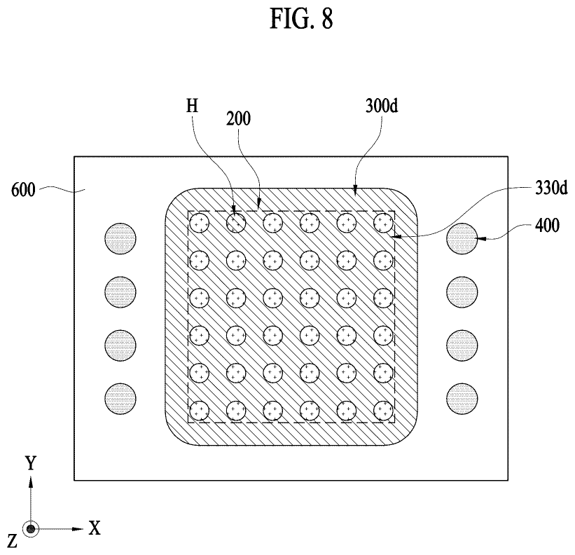

Referring to FIG. 8, according to an embodiment of the present inventive concept, a second reinforcement part 330d of a reinforcement structure 300d may cover the entire upper surface of the semiconductor die 200 based on the direction that is perpendicular to an upper surface of the first re-wiring layer 100 (the third direction Z). For example, the reinforcement structure 300d may cover the entire side of the semiconductor die 200. However, in this case, referring to FIG. 8, to fill the molding member 600 between the semiconductor die 200 and the second reinforcement part 330d, a hole H that penetrates the molding member 600 may be formed in the second reinforcement part 330d. A plurality of holes H may be distributed and formed in the second reinforcement part 333d so that the molding members 600 may penetrate evenly. By forming the holes H in the second reinforcement part 330d, penetration of the molding members 600 may proceed more smoothly.

For example, according to example embodiments of the present inventive concept, based on the direction that is perpendicular to the upper surface of the first re-wiring layer 100 (the third direction Z), at least some of the second reinforcement parts 330a, 330b, 330c and 330d may be provided between the semiconductor die 200 and the second re-wiring layer 500. In the third direction Z, the reinforcement structure 300 may be separated from the second re-wiring layer 500. Further, in the third direction Z, the reinforcement structure 300 may be separated from the semiconductor die 200.

According to the example embodiments of the present inventive concept, at least some of the second reinforcement parts 330a, 330b, 330c and 330d overlap the semiconductor die 200 in the direction that is perpendicular to the upper surface of the first re-wiring layer 100 (the third direction Z), and thus, stress that may be applied on the semiconductor die 200 may be more effectively resisted, and the durability of the semiconductor package 10 may be increased.

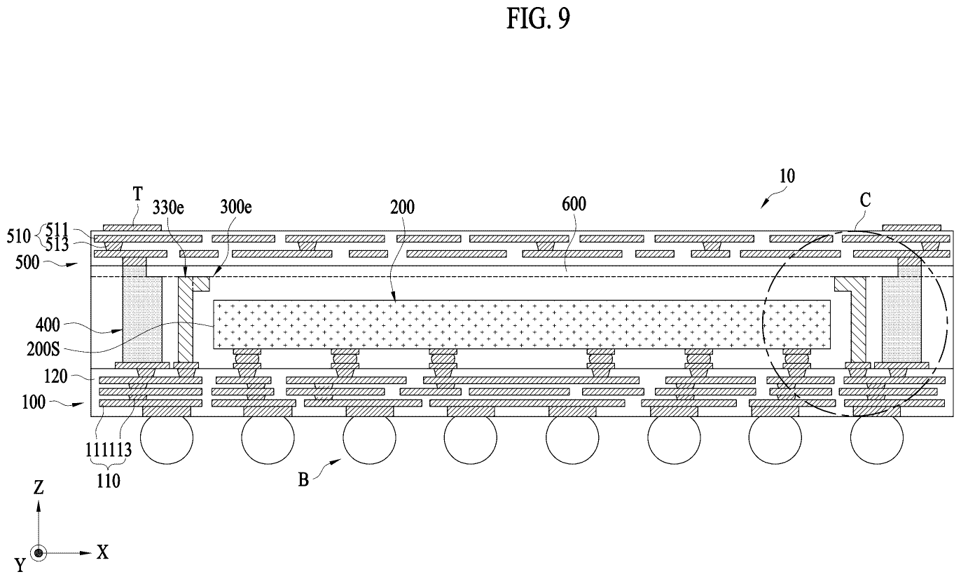

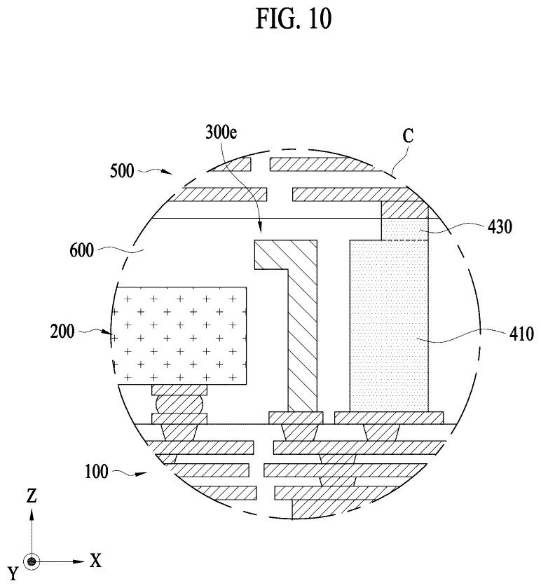

FIG. 9 illustrates a cross section of the semiconductor package 10 according to an example embodiment of the present inventive concept. FIG. 10 is an enlarged view of the part C of FIG. 9. Referring to FIGS. 9 and 10, the post 400 may include a first part 410 and a second part 430. A step may be formed between the first part 410 and the second part 430. The first part 410 may be connected to the first re-wiring layer 100. The second part 430 may be connected to the second re-wiring layer 500.

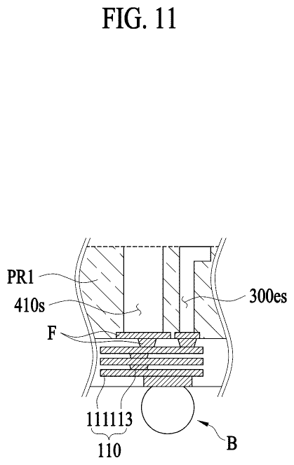

FIGS. 11 to 13 are diagrams explaining a method of forming the post 400 and a reinforcement structure 300e that are included in the semiconductor package 10. According to example embodiments of the present inventive concept, the post 400 and the reinforcement structure 300e may be formed by the photo process as described above or may be formed from parts that have already been manufactured. Hereinafter, the method of forming the post 400 and the reinforcement structure 300e by a photo process will be described in more detail with reference to FIGS. 11 to 13.

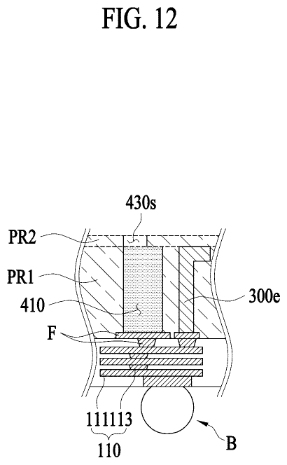

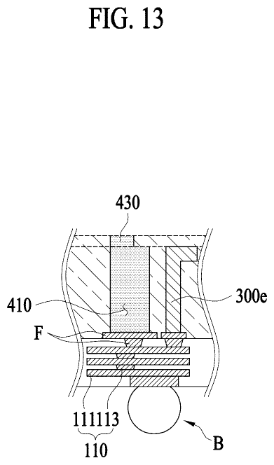

FIG. 11 is a diagram illustrating the process of forming the first part 410 of the post 400 and the reinforcement structure 300e that are included in the semiconductor package 10 according to an example embodiment of the present inventive concept. FIG. 12 is a diagram illustrating the process of forming the second part 430 of the post 400 that is included in the semiconductor package 10 according to an example embodiment of the present inventive concept. FIG. 13 is a diagram illustrating the formation of the reinforcement structure 300e, the first part 410 and the second part 430 of the post 400 that are included in the semiconductor package 10 according to an example embodiment of the present inventive concept.

Referring to FIG. 11, on a pad F that is electrically connected to the first re-wiring layer 100, a space 300es, in which the reinforcement structure 300e will be formed, and a space 410s, in which the first part 410 of the post 400 will be formed, may be formed in a first photoresistor PR1. Referring to FIG. 12, the space 300es, in which the reinforcement structure 300e will be formed, and the space 410s, in which the first part 410 of the post 400 will be formed, are empty spaces, and each of the spaces 300es and 410s may be filled with copper through a plating process. After forming the reinforcement structure 300 and the first part 410 of the post 400, a second photoresistor PR2 may be formed, and a space 430s, in which the second part 430 of the reinforcement structure 300 will be formed, may be formed in the second photoresistor PR2. Referring to FIG. 13, the space 430s, in which the second part 430 of the post 400 will be formed, is an empty space, and the space 430s may be filled with copper through a plating process. Since the first part 410 and the second part 430 of the post 400 are formed through multiple photo processes, a step may be formed between the formation of the first part 410 and the formation of the second part 430. As such, after forming the reinforcement structure 300 and the post 400 by the photo process, the first photoresistor PR1 and the second photoresistor PR2 may be removed by an etching process.

According to the method, the size of the reinforcement structure 300 and the post 400 may be adjusted depending on the size of the semiconductor die 200 and the semiconductor package 10. If the reinforcement structure 300 and the post 400 are formed through a photo process, it is easy to actively respond to changes in the size of the semiconductor die 200 and the semiconductor package 10. Thus, production efficiency may be increased and production costs may be reduced.

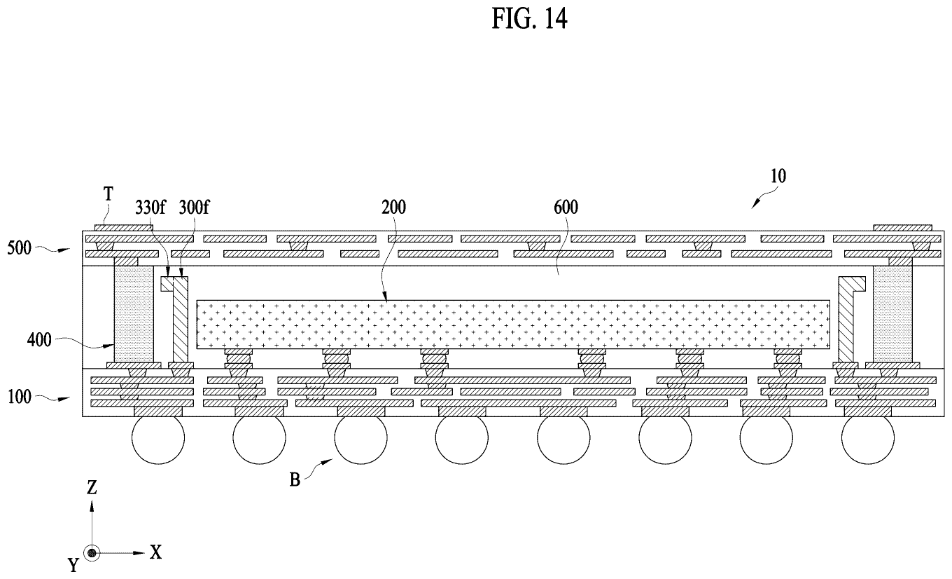

FIG. 14 is a cross-sectional view of a semiconductor package according to an example embodiment of the present inventive concept, and in which the second reinforcement part 330f may be formed to protrude in a horizontal direction toward the post 400 (the first direction X or the second direction Y). Since the protrusion direction of the second reinforcement part 330f is toward the post 400 in the horizontal direction (the first direction X or the second direction Y), the resistance to bending stress and shear stress that is transmitted from the outside of the semiconductor package 10 to the center of the semiconductor package 10 can be increased.

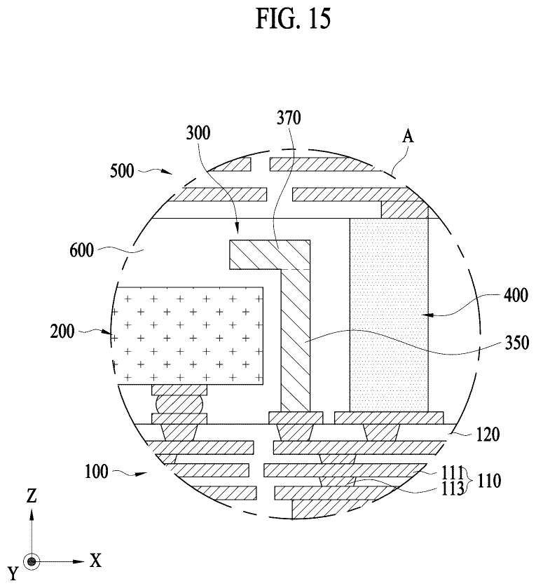

FIG. 15 is an enlarged view of the part A of FIG. 1.

Referring to FIG. 15, the reinforcement structure 300 may include a third reinforcement part 350 and a fourth reinforcement part 370.

According to example embodiments of the present inventive concept, the third reinforcement part 350 may be a rod-shaped structure that protrudes in the third direction Z and is disposed on the first re-wiring layer 100. The third reinforcement part 350 may be placed at a predetermined distance from the semiconductor die 200 in the horizontal direction (the first direction X or the second direction Y). The third reinforcement part 350 may be arranged to at least partially surround the semiconductor die 200. For example, the third reinforcement part 350 may be arranged to at least partially surround the semiconductor die 200 in horizontal directions (e.g., the first direction X and/or the second direction Y). The third reinforcement part 350 may have a substantially constant thickness.

According to example embodiments of the present inventive concept, the fourth reinforcement part 370 may be disposed on an end of the third reinforcement part 350. While disposed on the end of the third reinforcement part 350, the fourth reinforcement part 370 may extend in a horizontal direction toward the semiconductor die 200. For example, the thickness of the fourth reinforcement part 370 may be thicker than the thickness of the third reinforcement part 350; however, the present inventive concept is not limited thereto.

The third reinforcement part 350 may be located on a level that is below a level of the fourth reinforcement part 370 based on the direction that is perpendicular to the upper surface of the first re-wiring layer 100 (the third direction Z). At least a portion of the fourth reinforcement part 370 may overlap the third reinforcement part 350 in a direction that is perpendicular to the upper surface of the first re-wiring layer 100 (the third direction Z).

At least a portion of the fourth reinforcement part 370 may overlap the semiconductor die 200 based on the direction that is perpendicular to the upper surface of the first re-wiring layer 100 (the third direction Z).

However, the third reinforcement part 350 and the fourth reinforcement part 370 have different expressions and limitations from the reinforcement structure 300, which includes the first reinforcement part 310 and the second reinforcement part 330 described above. A more detailed description of the reinforcement structure 300 including the third reinforcement part 350 and the fourth reinforcement part 370 may at least be similar to a description of the reinforcement structure 300 including the first reinforcement part 310 and the second reinforcement part 330 described above, and may thus be omitted.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a first re-wiring layer comprising a first wiring;
a semiconductor die placed on the first re-wiring layer;
a post placed on the first re-wiring layer, and spaced apart from the semiconductor die, wherein the post is electrically connected to the first wiring; and
a reinforcement structure comprising a first reinforcement part and a second reinforcement part, wherein the first reinforcement part is placed on the first re-wiring layer, and is spaced apart from the semiconductor die and the post such that it is placed between the semiconductor die and the post, and wherein the second reinforcement part protrudes from the first reinforcement part.

2. The semiconductor package of claim 1, wherein the second reinforcement part is formed to protrude in a direction toward the semiconductor die.

3. The semiconductor package of claim 2, wherein at least a portion of the second reinforcement part is located on a level that is above a level of an upper surface of the semiconductor die based on a direction that is perpendicular to an upper surface of the first re-wiring layer.

4. The semiconductor package of claim 1, wherein the second reinforcement part is formed to protrude in a direction toward the post.

5. The semiconductor package of claim 1, wherein the first reinforcement part has a length shorter than the post based on a direction that is perpendicular to an upper surface of the first re-wiring layer.

6. The semiconductor package of claim 1, wherein the reinforcement structure comprises copper.

7. The semiconductor package of claim 1, further comprising a molding member covering an upper surface of the first re-wiring layer and at least partially surrounding the semiconductor die, the reinforcement structure and the post on the first re-wiring layer,
wherein the molding member fills spaces that are between the semiconductor die, the reinforcement structure and the post.

8. The semiconductor package of claim 7, wherein the reinforcement structure is completely surrounded by the molding member.

9. The semiconductor package of claim 7, further comprising a second re-wiring layer placed on the post and the molding member, and comprising a second wiring that is electrically connected to the post and the first wiring.

10. The semiconductor package of claim 9, wherein the reinforcement structure is spaced apart from the second re-wiring layer based on a direction that is perpendicular to the upper surface of the first re-wiring layer.

11. The semiconductor package of claim 9, further comprising an external terminal placed on the second re-wiring layer, and electrically connected to the second re-wiring layer.

12. The semiconductor package of claim 11, wherein the external terminal overlaps the post based on a direction that is perpendicular to the upper surface of the first re-wiring layer.

13. A semiconductor package comprising:
a first re-wiring layer comprising a first wiring;
a semiconductor die placed on the first re-wiring layer;
a post placed on the first re-wiring layer, and spaced apart from the semiconductor die, wherein the post is electrically connected to the first wiring; and
a reinforcement structure comprising a third reinforcement part and a fourth reinforcement part, wherein the third reinforcement part is placed on the first re-wiring layer, and is spaced apart from the semiconductor die and the post such that it is placed between the semiconductor die and the post, wherein the third reinforcement part has a substantially constant thickness, and wherein the fourth reinforcement part is connected to the third reinforcement part and has a thickness that is thicker than that of the third reinforcement part.

14. The semiconductor package of claim 13, wherein the third reinforcement part is located on a level that is below a level of the fourth reinforcement part based on a direction that is perpendicular to an upper surface of the first re-wiring layer.

15. The semiconductor package of claim 14, wherein the fourth reinforcement part is arranged to be spaced apart from the first re-wiring layer based on the direction that is perpendicular to the upper surface of the first re-wiring layer.

16. The semiconductor package of claim 15, wherein at least a portion of the fourth reinforcement part overlaps the semiconductor die based on the direction that is perpendicular to the upper surface of the first re-wiring layer.

17. The semiconductor package of claim 13, further comprising a molding member covering an upper surface of the first re-wiring layer and at least partially surrounding the semiconductor die, the reinforcement structure and the post on the first re-wiring layer,
wherein the molding member fills spaces that are between the semiconductor die, the reinforcement structure and the post.

18. The semiconductor package of claim 17, wherein the reinforcement structure is completely surrounded by the molding member.

19. A semiconductor package comprising:
a first re-wiring layer comprising a first wiring;
a semiconductor die placed on the first re-wiring layer;
a post placed on the first re-wiring layer, and spaced apart from the semiconductor die, wherein the post is electrically connected to the first wiring;
a reinforcement structure comprising a first reinforcement part and a second reinforcement part, wherein the first reinforcement part is placed on the first re-wiring layer, and is spaced apart from the semiconductor die and the post, and wherein the second reinforcement part protrudes from the first reinforcement part in a direction toward the semiconductor die;
a molding member covering an upper surface of the first re-wiring layer and at least partially surrounding the semiconductor die, the reinforcement structure and the post on the first re-wiring layer, wherein the molding member fills spaces that are between the semiconductor die, the reinforcement structure and the post; and
a second re-wiring layer placed on the post and the molding member, and comprising a second wiring that is electrically connected to the post and the first wiring.

20. The semiconductor package of claim 19, wherein the reinforcement structure is completely surrounded by the molding member.
